(19) United States
(12) Patent Application Publication
(10) Pub. No.: US 2017/0345747 A1
(43) Pub. Date: Nov. 30, 2017

(54) MULTILAYER SUBSTRATE AND MANUFACTURING METHOD FOR SAME

(71) Applicant: KYOCERA Corporation, Kyoto-shi (JP)

(72) Inventor: Yoshinori NAKATOMI, Nagahama-shi (JP)

(73) Assignee: KYOCERA Corporation, Kyoto-shi (JP)

(21) Appl. No.: 15/604,881

(22) Filed: May 25, 2017

(30) Foreign Application Priority Data
May 26, 2016 (JP) 2016-105063

(51) Int. Cl. H01L 23/498; H01L 21/56; H01L 21/52; H01L 23/31; H01L 21/48

(52) U.S. Cl. CPC H01L 23/49822; H01L 23/49838; H01L 23/49827; H01L 23/49811; H01L 23/3142; H01L 21/4853; H01L 21/52; H01L 21/4875; H01L 21/486; H01L 21/4857; H01L 21/565

(57) ABSTRACT

A multilayer substrate includes a component mounting substrate having component mounting and non-mounting surfaces and including connection pads on both the mounting surfaces, a sealing resin layer having an upper surface in close contact with the non-mounting surface and a flat lower surface, a semiconductor element having an electrode formation surface on which electrodes are formed, and embedded in the sealing resin layer with the electrode formation surface exposed at the flat lower surface, an insulating layer formed in close contact with the electrode formation surface and the flat lower surface, through-holes continuously penetrating through the insulating layer and the sealing resin layer and having bottom ends defined by the connection pads on the non-mounting substrate, via holes penetrating through the insulating layer and having bottom ends defined by the electrodes, and wiring conductors formed inside the through-holes and the via holes and on a surface of the insulating layer.

### BACKGROUND OF THE INVENTION

### Field of the Invention

The present invention relates to a multilayer substrate including a plurality of laminated wiring substrates, and to a manufacturing method for the multilayer substrate.

### SUMMARY OF THE INVENTION

An object of the present invention is to provide a multilayer substrate capable of ensuring stable operations of a semiconductor element and an electronic component.

The present invention provides a multilayer substrate including a component mounting substrate having a component mounting surface and a component non-mounting surface, and including connection pads formed on both the mounting surfaces in a state electrically connected to each other, a sealing resin layer having an upper surface and a flat lower surface, the upper surface being formed in close contact with the non-mounting surface, a semiconductor element having an electrode formation surface on which a plurality of electrodes is formed, the semiconductor element being embedded in the sealing resin layer in a state that the electrode formation surface is exposed at the flat lower surface, an insulating layer formed in close contact with the electrode formation surface and the lower surface of the sealing resin layer, through-holes continuously penetrating through the insulating layer and the sealing resin layer and having bottom ends defined by the connection pads on the non-mounting substrate, via holes penetrating through the insulating layer and having bottom ends defined by the electrodes, and wiring conductors formed inside the through-holes and the via holes and on a surface of the insulating layer.

According to the multilayer substrate of the present invention, the non-mounting surface of the component mounting substrate and the sealing resin layer are formed in close contact with each other. Therefore, even when thermal stress generates between the component mounting substrate and the sealing resin layer due to difference in thermal expansion and contraction between both the members, the thermal expansion and contraction being caused by heating of the mounted semiconductor element and the mounted electronic component, the thermal stress can be dispersed through a close contact region between the non-mounting surface and the sealing resin layer. It is hence possible to avoid the thermal stress from concentrating at junctions between the connection pads and the wiring conductors inside the through-holes, both establishing electrical connection between the semiconductor element and the electronic component, and to prevent the occurrence of cracking.

As a result, the multilayer substrate ensuring stable operations of the semiconductor element and the electronic component can be obtained.

The present invention further provides a manufacturing method for a multilayer substrate, the manufacturing method including a step of preparing a semiconductor element having an electrode formation surface on which a plurality of electrodes is formed, and a base plate, a step of placing the semiconductor element on the base plate with the electrode formation surface facing the base plate, a step of preparing a component mounting substrate having a component mounting surface and a component non-mounting surface, and including connection pads formed on both the mounting surfaces in a state electrically connected to each other, a step of arranging the component mounting substrate and the base plate including the semiconductor element placed thereon in an opposing relation with a gap kept between the semiconductor element on the base plate and the non-mounting surface, and filling a sealing resin into between each of the base plate and the semiconductor element and the component mounting substrate, a step of separating the base plate from the semiconductor element and the sealing resin, and forming a sealing resin layer having a flat surface at which the electrode formation surface is exposed, the sealing resin layer being formed in close contact with the non-mounting surface of the component mounting substrate, a step of forming an insulating layer in close contact with the electrode formation surface and the flat surface, a step of forming through-holes continuously penetrating through the insulating layer and the sealing resin layer and having bottom ends defined by the connection pads on the non-mounting substrate, and via holes penetrating through the insulating layer and having bottom ends defined by the electrodes, and a step of forming wiring conductors inside the through-holes and the via holes and on a surface of the insulating layer.

According to the manufacturing method for the multilayer substrate of the present invention, after forming the sealing resin layer in close contact with the non-mounting surface of the component mounting substrate, the insulating layer is formed in close contact with the electrode formation surface of the semiconductor element and the flat surface of the sealing resin layer. The through-holes continuously penetrating through the insulating layer and the sealing resin layer and having the bottom ends defined by the connection pads on the non-mounting surface, and the via holes penetrating through the insulating layer and having the bottom ends defined by the electrodes are then formed. By further forming the wiring conductors inside the through-holes and the via holes and on the surface of the insulating layer, the semiconductor element and the component mounting substrate are electrically connected.

Thus, because of the non-mounting surface of the component mounting substrate and the sealing resin layer being formed in close contact with each other, even when thermal stress generates between the component mounting substrate and the sealing resin layer due to difference in thermal expansion and contraction between both the members, the thermal expansion and contraction being caused by heating of the mounted semiconductor element and the mounted electronic component, the thermal stress can be dispersed through a close contact region between the non-mounting surface and the sealing resin layer. It is hence possible to avoid the thermal stress from concentrating at junctions between the connection pads and the wiring conductors inside the through-holes, both establishing electrical connection between the semiconductor element and the electronic component, and to prevent the occurrence of cracking.

As a result, the multilayer substrate capable of ensuring stable operations of the semiconductor element and the electronic component can be obtained with the manufacturing method of the present invention.

### BRIEF DESCRIPTION OF THE DRAWINGS

FIG. 1 is a schematic sectional view of an example of a multilayer substrate according to the present invention;

FIGS. 2A, 2B, 2C and 2D are schematic sectional views referenced to explain practical examples of individual steps in a manufacturing method for the multilayer substrate according to the present invention; and

FIGS. 3A, 3B and 3C are schematic sectional views referenced to explain practical examples of individual steps in the manufacturing method for the multilayer substrate according to the present invention.

### DESCRIPTION OF THE PREFERRED EMBODIMENTS

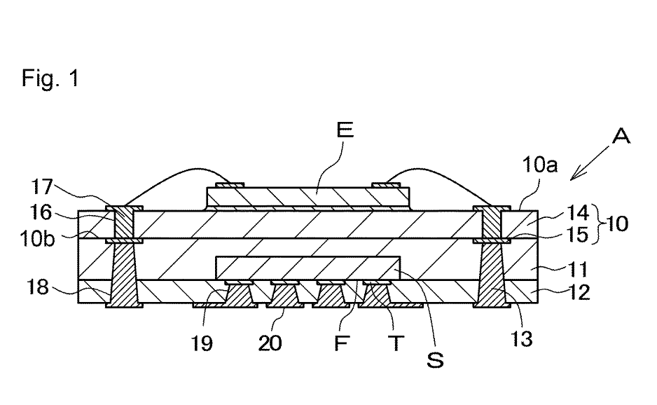

To begin with, an example of a multilayer substrate A according to the present invention is described with reference to FIG. 1.

As illustrated in FIG. 1, the multilayer substrate A according to the present invention includes, for example, a component mounting substrate 10, a sealing resin layer 11, a semiconductor element S, an insulating layer 12, and wiring conductors 13.

The component mounting substrate 10 includes, for example, an insulating plate 14 and connection pads 15. The component mounting substrate 10 has a component mounting surface 10a and a component non-mounting surface 10b. An electronic component E is mounted on the component mounting surface 10a, and the component non-mounting surface 10b is positioned in close contact with the sealing resin layer 11.

The insulating plate 14 is made of, for example, glass cloth impregnated with a thermosetting resin such as an epoxy resin or a bismaleimide-triazine resin, and it has a plurality of connection holes 16.

The connection pads 15 are each made of, for example, a metal having good electrical conductivity, such as copper, and are formed on the mounting surface 10a and the non-mounting surface 10b. Electrodes of the electronic component E are electrically connected to the connection pads 15 on the mounting surface 10a through bonding wires, for example. The connection pads 15 on both the surfaces 10a and 10b are electrically connected to each other by connection conductors 17 in the connection holes 16. The connection conductors 17 are made of, for example, copper or a conductive resin.

The sealing resin layer 11 is made of, for example, a thermosetting resin such as an epoxy resin or a polyurethane resin. The sealing resin layer 11 has an upper surface and a flat lower surface. The upper surface of the sealing resin layer 11 is formed in close contact with the component mounting substrate 10.

The semiconductor element S is, for example, a microprocessor or a semiconductor memory, and is made of silicon or germanium. The semiconductor element S has an electrode formation surface F on which a plurality of electrodes T is formed.

The semiconductor element S is embedded in the sealing resin layer 11 in a state that the electrode formation surface F is exposed at the flat lower surface of the sealing resin layer 11.

The sealing resin layer 11 protects the semiconductor element S against external environments.

The insulating layer 12 is made of, for example, a thermosetting resin such as an epoxy resin or a bismaleimide-triazine resin.

The insulating layer 12 is formed in close contact with the electrode formation surface F and the flat lower surface of the sealing resin layer 11.

A plurality of through-holes 18 is formed in the insulating layer 12 and the sealing resin layer 11 in a state continuously penetrating through both the layers and having bottom ends defined by the connection pads 15 on the non-mounting surface 10b.

Furthermore, a plurality of via holes 19 is formed in the insulating layer 12 in a state penetrating through the insulating layer 12 and having bottom ends defined by the electrodes T.

Diameters of the through-holes 18 and diameters of the via holes 19 are about 10 to 100 μm.

The wiring conductors 13 are made of, for example, a metal having good electrical conductivity, such as non-electrolytic copper plating or electrolytic copper plating, and are formed on a lowermost surface of the insulating layer 12, inside the through-holes 18, and inside the via holes 19.

The wiring conductors 13 inside the through-holes 18 are electrically connected to the connection pads 15.

The wiring conductors 13 inside the via holes 19 are electrically connected to the electrodes T.

Circuit board connection pads 20 are formed on the lowermost surface of the insulating layer 12 by parts of the wiring conductor 13 thereon. Electrodes of a circuit board on which the multilayer substrate A is mounted are connected to the circuit board connection pads 20 through solders.

The semiconductor element S and the electronic component E operate with electric signals transferred between each of the semiconductor element S and the electronic component E and the circuit board.

According to the multilayer substrate A of the present invention, as described above, the non-mounting surface 10b of the component mounting substrate 10 and the sealing resin layer 11 are formed in close contact with each other. Therefore, even when thermal stress generates between the component mounting substrate 10 and the sealing resin layer 11 due to thermal expansion and contraction of both the members with heating of the semiconductor element S and the electronic component E, the thermal stress can be dispersed through a close contact region between the non-mounting surface 10b and the sealing resin layer 11. It is hence possible to avoid the thermal stress from concentrating at junctions between the connection pads 15 and the wiring conductors 13 inside the through-holes 18, both establishing electrical connection between the semiconductor element S and the electronic component E, and to prevent the occurrence of cracking.

As a result, the multilayer substrate A capable of ensuring stable operations of the semiconductor element S and the electronic component E can be obtained.

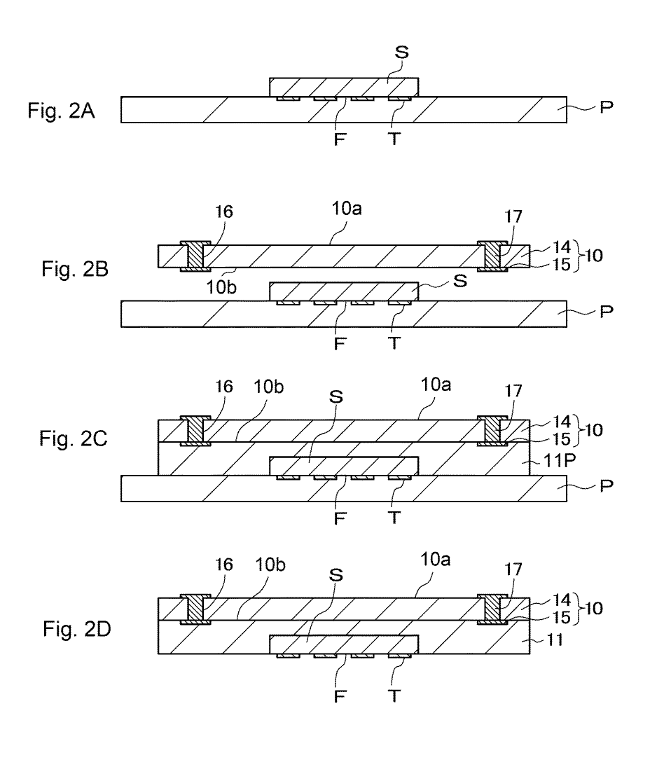

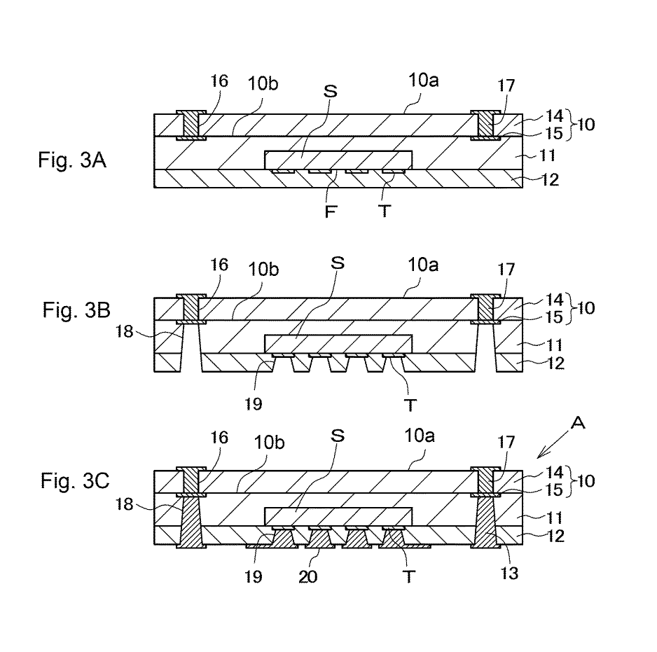

Practical examples of individual steps in a manufacturing method for the multilayer substrate according to the present invention will be described below with reference to FIGS. 2A to 2D and FIGS. 3A to 3C. The same members as those in FIG. 1 are denoted by the same reference signs, and description of those members is omitted.

Although FIGS. 2A to 2D and FIGS. 3A to 3C illustrate the practical examples of the individual steps for one semiconductor element S, the manufacturing method may be carried out by performing respective processes of the individual steps for a plurality of semiconductor elements S together, and by dividing the plurality of semiconductor elements S into the separate elements after the final step.

First, as illustrated in FIG. 2A, the semiconductor element S having the electrode formation surface F on which the plurality of electrodes T is formed, and a base plate P are prepared.

Then, the semiconductor element S is placed on the base plate P with the electrode formation surface F facing the base plate P.

The base plate P is formed of glass, for example, and a low-adhesive layer (not illustrated) for temporarily fixing the semiconductor element S is formed on an upper surface of the base plate P.

Next, as illustrated in FIG. 2B, the component mounting substrate 10 having the component mounting surface 10a and the component non-mounting surface 10b is prepared. The component mounting substrate 10 and the base plate P including the semiconductor element S placed thereon are then arranged in an opposing relation with a gap kept between the semiconductor element S on the base plate P and the non-mounting surface 10b.

Next, as illustrated in FIG. 2C, a sealing resin 11P is filled into between each of the base plate P and the semiconductor element S and the component mounting substrate 10, and is then cured.

The sealing resin 11P is filled in a following manner, for example. The component mounting substrate 10 is placed in a lower die with the non-mounting surface 10b facing upward, and the sealing resin layer 11P is applied over the non-mounting surface 10b. The base plate P including the semiconductor element S mounted thereon is placed in an upper die with the semiconductor element S facing downward. In such a state, the upper die and the lower die are pressed against to each other such that the semiconductor element S is embedded in the sealing resin 11P.

Next, as illustrated in FIG. 2D, the base plate P is separated from the semiconductor element S and the sealing resin 11P. Thus, the sealing resin layer 11 is formed which has a flat surface where the electrode formation surface F is exposed, and which is formed in close contact with the non-mounting surface 10b of the component mounting substrate 10.

Next, as illustrated in FIG. 3A, the insulating layer 12 is formed over the electrode formation surface F and the flat surface of the sealing resin layer 11.

The insulating layer 12 is formed, for example, in a manner of preparing a film by dispersing an inorganic insulating filler into a not-yet-cured composition of an epoxy resin or a bismaleimide-triazine resin, and bonding the film to the electrode formation surface F and the flat surface of the sealing resin layer 11 by thermal pressure bonding under a vacuum state.

Next, as illustrated in FIG. 3B, the through-holes 18 continuously penetrating through the insulating layer 12 and the sealing resin layer 11 and having the bottom ends defined by the connection pads 15 on the non-mounting surface 10b, and the via holes 19 penetrating through the insulating layer 12 and having the bottom ends defined by the electrodes T are formed.

The through-holes 18 and the via holes 19 are formed using a laser, for example.

Next, as illustrated in FIG. 3C, the wiring conductors 13 are formed inside the through-holes 18 and the via holes 19, and on the lowermost surface of the insulating layer 12.

The wiring conductors 13 are formed, for example, by applying a coating of a conductor pattern, which is made of non-electrolytic copper plating or electrolytic copper plating, with the known semi-additive process.

As a result, the multilayer substrate A illustrated in FIG. 1 is fabricated.

According to the manufacturing method for the multilayer substrate of the present invention, as described above, after forming the sealing resin layer 11 in close contact with the non-mounting surface 10b of the component mounting substrate 10, the insulating layer 12 is formed in close contact with the electrode formation surface F of the semiconductor element S and the flat surface of the sealing resin layer 11. The through-holes 18 continuously penetrating through the insulating layer and the sealing resin layer 11 and having the bottom ends defined by the connection pads 15 on the non-mounting surface 10b, and the via holes 19 penetrating through the insulating layer 12 and having the bottom ends defined by the electrodes T are then formed. By further forming the wiring conductors 13 inside the through-holes 18 and the via holes 19 and on the surface of the insulating layer 12, the semiconductor element S and the component mounting substrate 10 are electrically connected. In addition, the electrodes of the electronic component E are electrically connected to the connection pads 15 on the mounting surface 10a through bonding wires, for example.

Thus, because of the non-mounting surface 10b of the component mounting substrate 10 and the sealing resin layer 11 being formed in close contact with each other, even when thermal stress generates between the component mounting substrate 10 and the sealing resin layer 11 due to difference in thermal expansion and contraction between both the members, the thermal expansion and contraction being caused by heating of the mounted semiconductor element S and the mounted electronic component E, the thermal stress can be dispersed through a close contact region between the component mounting substrate 10 and the sealing resin layer 11. It is hence possible to avoid the thermal stress from concentrating at junctions between the connection pads 15 and the wiring conductors 13 inside the through-holes 18, both establishing electrical connection between the semiconductor element S and the electronic component E, and to prevent the occurrence of cracking.

As a result, the multilayer substrate capable of ensuring stable operations of the semiconductor element and the electronic component can be obtained with the manufacturing method of the present invention.

It is to be noted that the present invention is not limited to the above-described exemplary embodiment, and that the present invention can be variously modified insofar as not departing from the gist of the present invention. For instance, while the above exemplary embodiment has been described in connection with the case where the component mounting substrate 10 and the insulating layer 12 are each in the form of a single layer, each of those members may have a multilayer structure.

Furthermore, while the above exemplary embodiment has been described in connection with the case where a solder resist layer is not coated on the surface of the multilayer substrate A, the solder resist layer may be coated thereon.

What is claimed is:

1. A multilayer substrate comprising:
a component mounting substrate comprising a component mounting surface, a component non-mounting surface, and connection pads formed on both the mounting surfaces in a state electrically connected to each other;
a sealing resin layer comprising an upper surface and a flat lower surface, the upper surface being formed in close contact with the non-mounting surface;
a semiconductor element comprising an electrode formation surface on which a plurality of electrodes is formed, the semiconductor element being embedded in the sealing resin layer in a state that the electrode formation surface is exposed at the flat lower surface;
an insulating layer formed in close contact with the electrode formation surface and the lower surface of the sealing resin layer;
through-holes continuously penetrating through the insulating layer and the sealing resin layer and comprising bottom ends defined by the connection pads on the non-mounting substrate;
via holes penetrating through the insulating layer and comprising bottom ends defined by the electrodes; and
wiring conductors formed inside the through-holes and the via holes and on a surface of the insulating layer.

2. A manufacturing method for a multilayer substrate, the manufacturing method comprising steps of:
preparing a semiconductor element comprising an electrode formation surface on which a plurality of electrodes is formed, and a base plate;
placing the semiconductor element on the base plate with the electrode formation surface facing the base plate;
preparing a component mounting substrate comprising a component mounting surface, a component non-mounting surface, and connection pads formed on both the mounting surfaces in a state electrically connected to each other;
arranging the component mounting substrate and the base plate including the semiconductor element placed thereon in an opposing relation with a gap kept between the semiconductor element on the base plate and the non-mounting surface, and filling a sealing resin into between each of the base plate and the semiconductor element and the component mounting substrate;
separating the base plate from the semiconductor element and the sealing resin, and forming a sealing resin layer comprising a flat surface at which the electrode formation surface is exposed, the sealing resin layer being formed in close contact with the non-mounting surface of the component mounting substrate;
forming an insulating layer in close contact with the electrode formation surface and the flat surface;
forming through-holes continuously penetrating through the insulating layer and the sealing resin layer and comprising bottom ends defined by the connection pads on the non-mounting substrate, and via holes penetrating through the insulating layer and comprising bottom ends defined by the electrodes; and
forming wiring conductors inside the through-holes and the via holes and on a surface of the insulating layer.
